(19) United States
(12) Patent Application Publication
(10) Pub. No.: US 2024/0179998 A1
(43) Pub. Date: May 30, 2024

(54) DISPLAY DEVICE AND METHOD OF MANUFACTURING THE SAME

(71) Applicant: Samsung Display Co., Ltd., Yongin-si (KR)

(72) Inventors: Hyuneok Shin, Yongin-si (KR); Sungjoo Kwon, Yongin-si (KR); Sanggab Kim, Yongin-si (KR); Dokeun Song, Yongin-si (KR)

(73) Assignee: Samsung Display Co., Ltd., Yongin-si (KR)

(21) Appl. No.: 18/517,168

(22) Filed: Nov. 22, 2023

(30) Foreign Application Priority Data
Nov. 25, 2022 (KR) 10-2022-0160794

(51) Int. Cl. H10K 59/80; H10K 59/12

(52) U.S. Cl. CPC H10K 59/80517; H10K 59/1201

(57) ABSTRACT

A display device includes a substrate, a pixel circuit layer disposed on the substrate and including at least one thin film transistor, and a pixel electrode disposed on the pixel circuit layer and electrically connected to the at least one thin film transistor, wherein the pixel electrode includes a lower layer including aluminum, an intermediate layer disposed on the lower layer and including a tungsten oxide, and an upper layer disposed on the intermediate layer and including a transparent conductive oxide.

### CROSS-REFERENCE TO RELATED APPLICATION(S)

This application claims priority to and benefits of Korean Patent Application No. 10-2022-0160794 under 35 U.S.C. § 119, filed on Nov. 25, 2022, in the Korean Intellectual Property Office, the entire contents of which are incorporated herein by reference.

### BACKGROUND

### 1. Technical Field

One or more embodiments relate to a display device and a method of manufacturing the display device.

### 2. Description of the Related Art

Display devices provide visual information, such as images or videos, to users. With the development of various electronic devices, such as computers, large TVs, and the like, various types of display devices applicable thereto have been developed. Mobility-based electronic devices have been widely used, and recently, tablet PCs are widely used as mobile electronic devices, in addition to compact electronic devices such as mobile phones.

A display device may include a display area and a non-display area, and a plurality of light-emitting elements are arranged in the display area. A display device may provide an image through light emitted by the light-emitting elements. The light-emitting elements may include a pixel electrode and a counter electrode.

### SUMMARY

One or more embodiments include a display device with improved reliability and a method of manufacturing the display device.

However, embodiments of the disclosure are not limited to those set forth herein. The above and other embodiments will become more apparent to one of ordinary skill in the art to which the disclosure pertains by referencing the detailed description of the disclosure given below.

According to one or more embodiments, a display device may include a substrate, a pixel circuit layer disposed on the substrate and including at least one thin film transistor, and a pixel electrode disposed on the pixel circuit layer and electrically connected to the at least one thin film transistor, wherein the pixel electrode may include a lower layer including aluminum, an intermediate layer disposed on the lower layer and including a tungsten oxide, and an upper layer disposed on the intermediate layer and including a transparent conductive oxide.

In an embodiment, the lower layer may include an Al—Ti alloy.

In an embodiment, in the Al—Ti alloy, an atomic ratio of titanium (Ti) may have a range of about 0.01 at % to about 0.1 at %.

In an embodiment, the upper layer may include an indium tin oxide (ITO).

In an embodiment, the thickness of the upper layer may be in a range of about 20 Å to about 100 Å.

In an embodiment, the substrate may be a semiconductor substrate including a semiconductor material.

In an embodiment, the display device may further include a light-emitting layer disposed on the pixel electrode, a counter electrode disposed on the light-emitting layer, and a thin film encapsulation layer disposed on the counter electrode.

In an embodiment, the display device may further include a red color filter, a green color filter, and a blue color filter disposed on the thin film encapsulation layer.

According to one or more embodiments, a display device may include a substrate, a pixel circuit layer disposed on the substrate and including at least one thin film transistor, and a pixel electrode disposed on the pixel circuit layer and electrically connected to the at least one thin film transistor, wherein the pixel electrode may include a lower layer including aluminum, an intermediate layer disposed on the lower layer and including a tungsten oxide, and an upper layer disposed on the intermediate layer and including an ITO.

In an embodiment, the lower layer may include an Al—Ti alloy, and in the Al—Ti alloy, an atomic ratio of Ti may have a range of about 0.01 at % to about 0.1 at %.

In an embodiment, the thickness of the upper layer may be in a range of about 20 Å to about 100 Å.

In an embodiment, the substrate may include a semiconductor substrate.

According to one or more embodiments, a method of manufacturing a display device may include forming, on a substrate, a pixel circuit layer including at least one thin film transistor, forming, on the pixel circuit layer, a preliminary lower conductive layer electrically connected to the at least one thin film transistor and including aluminum, forming, on the lower conductive layer, a preliminary intermediate conductive layer including a tungsten oxide, forming, on the preliminary intermediate conductive layer, a preliminary upper conductive layer including a transparent conductive oxide, and forming a pixel electrode including a lower layer, an intermediate layer, and an upper layer by dry etching the preliminary lower conductive layer, preliminary the intermediate conductive layer, and the preliminary upper conductive layer.

In an embodiment, the forming of the pixel electrode may include a first etching operation of dry etching the preliminary upper conductive layer, and a second etching operation of dry etching the preliminary lower conductive layer and the preliminary intermediate conductive layer.

In an embodiment, the second etching operation of dry etching the preliminary lower conductive layer and the preliminary intermediate conductive layer may be performed by using a chlorine-based etching gas.

In an embodiment, the preliminary lower conductive layer may include an Al—Ti alloy.

In an embodiment, in the Al—Ti alloy, an atomic ratio of Ti may have a range of about 0.01 at % to about 0.1 at %.

In an embodiment, the preliminary upper conductive layer may include an indium tin oxide (ITO).

In an embodiment, the thickness of the preliminary upper conductive layer may be in a range of about 20 Å to about 100 Å.

In an embodiment, the substrate may include a semiconductor substrate.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic perspective view of a display device according to an embodiment;

FIG. 2 is a schematic cross-sectional view of a display device according to an embodiment;

FIG. 3 is a schematic cross-sectional view of a display device according to an embodiment;

FIG. 4 is a graph showing the reflectivities of aluminum and an aluminum alloy; and

FIGS. 5 to 9 are schematic cross-sectional views of a method of manufacturing a display device, according to an embodiment.

### DETAILED DESCRIPTION OF THE EMBODIMENTS

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the invention.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the X-axis, the Y-axis, and the Z-axis are not limited to three axes of a rectangular coordinate system, such as the x, y, and z axes, and may be interpreted in a broader sense. For example, the X-axis, the Y-axis, and the Z-axis may be perpendicular to one another, or may represent different directions that are not perpendicular to one another. For the purposes of this disclosure, “at least one of A and B” may be construed as understood to mean A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the invention. Further, the blocks, units, and/or modules of some embodiments may be physically combined into more complex blocks, units, and/or modules without departing from the scope of the invention.

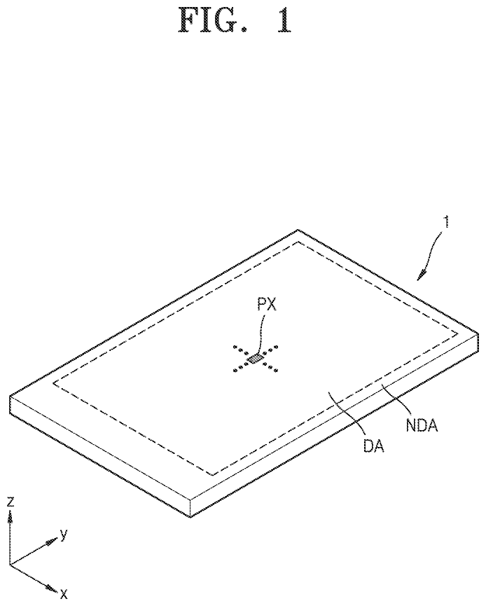

FIG. 1 is a schematic perspective view of a display device 1 according to an embodiment.

Referring to FIG. 1, the display device 1 may include a display area DA and a non-display area NDA positioned outside the display area DA. The display device 1 may provide an image in the display area DA through an array of pixels PX. The pixels PX may be defined as an emission area in which a light-emitting element driven by a pixel circuit emits light. For example, an image may be provided by the light emitted by light-emitting element through the pixels PX. Not only the light-emitting elements and pixel circuits, but also various signal wires and power wires, and the like, which are connected (e.g., electrically connected) to the pixel circuits, may be arranged in the display area DA.

The non-display area NDA, as an area that does not provide an image, may entirely or partially surround the display area DA. Various wires, driving circuits, and the like to provide electrical signals or power to the display area DA may be arranged in the non-display area NDA.

The display device 1, when viewed in a direction perpendicular to a surface of the display device 1, may have an approximately rectangular shape. For example, the display device 1 may have, as illustrated in FIG. 1, an approximately rectangular plane shape with short sides extending in an x-axis direction and long sides extending in a y-axis direction. A corner portion where the short side in the x-axis direction meets the long side in the y-axis direction may have a right-angle shape or a round shape having a certain curvature. The plane shape of the display device 1 is not limited to a rectangular shape, and the display device 1 may have various shapes, such as a polygonal shape, for example, a triangle and the like, a circular shape, an oval shape, an amorphous shape, and the like.

Although FIG. 1 illustrates the display device 1 having a flat display surface, embodiments are not limited thereto. In another example, the display device 1 may include a three-dimensional display surface or a curved display surface. In case that the display device 1 includes a three-dimensional display surface, the display device 1 may include display areas facing in different directions, for example, a polygonal column type display surface. In another example, in case that the display device 1 includes a curved display surface, the display device 1 may be implemented in various shapes, such as a flexible, foldable, or rollable display device, and the like.

The display device 1 may be used as display screens of various products including not only portable electronic devices, such as a mobile phone, a smart phone, a tablet personal computer (PC), a mobile communication terminal, an electronic organizer, an electronic book, a portable multimedia player (PMP), a navigation device, an ultra-mobile PC (UMPC), and the like, but also televisions, notebooks, monitors, billboards, Internet of things (IOT), and the like. Furthermore, the display device 1 according to an embodiment may be used for wearable devices, such as a smart watch, a watch phone, a glasses type display, a head mounted display (HMD), and the like. Furthermore, the display device 1 according to an embodiment may be used as an instrument panel of a vehicle, a center information display (CID) disposed in the center fascia or dashboard of a vehicle, a room mirror display in lieu of a side mirror of a vehicle, or a display screen disposed at the rear surface of a front seat as an entertainment device for a rear seat of a vehicle.

Furthermore, although the display device 1 is described below as including an organic light-emitting diode (OLED) as the light-emitting element, the display device 1 according to one or more embodiments is not limited thereto. In another example, the display device 1 may be a light-emitting display device including an inorganic light-emitting diode, e.g., an inorganic light-emitting display device. In another example, the display device 1 may be a quantum-dot light-emitting display device.

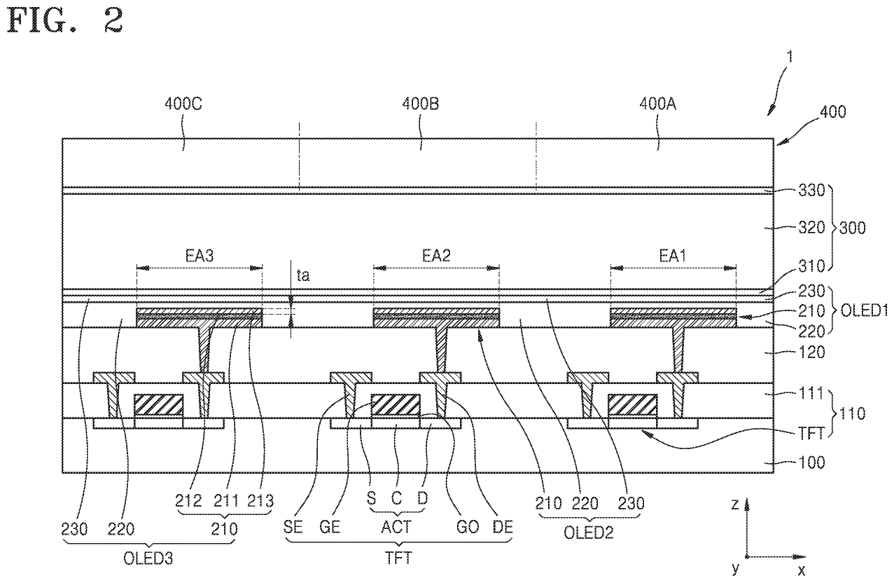

FIG. 2 is a schematic cross-sectional view of the display device 1 according to an embodiment.

Referring to FIG. 2, the display device 1 may include a substrate 100, a pixel circuit layer 110 including a thin film transistor TFT, a via insulating layer 120 disposed on the pixel circuit layer 110, and first to third organic light-emitting diodes OLED1, OLED2, and OLED3 disposed on the via insulating layer 120. The display device 1 may further include a thin film encapsulation layer 300 disposed on the first to third organic light-emitting diodes OLED1, OLED2, and OLED3 and a color filter layer 400 disposed on the thin film encapsulation layer 300.

The substrate 100 may have an upper surface extending in the x-axis direction and the y-axis direction. The substrate 100 may include a semiconductor material, for example, a Group IV semiconductor, a Group III-V compound semiconductor, or a Group II-VI compound semiconductor. The substrate 100 may include a silicon layer. For example, the substrate 100 may be a semiconductor substrate including a semiconductor material. However, the type of the substrate 100 is not limited to a semiconductor substrate. For example, the substrate 100 may include polymer resin, such as glass or polyethersulfone, polyarylate, polyetherimide, polyethylene naphthalate, polyethylene terephthalate, polyphenylene sulfide, polyimide, polycarbonate, cellulose triacetate, cellulose acetate propionate, and the like. In an embodiment, the substrate 100 may have a multilayer structure including a base layer including the polymer resin described above and a barrier layer. In the following description, a case in which the substrate 100 includes a semiconductor material is described in detail.

The pixel circuit layer 110 may be disposed on the substrate 100. The pixel circuit layer 110 may include a pixel circuit connected to an organic light-emitting diode, and insulating layers. The pixel circuit layer 110 may include at least one thin film transistor TFT and an interlayer insulating layer 111, which are disposed on the substrate 100.

The thin film transistor TFT may include a gate dielectric layer GO, a gate electrode GE, and an active area ACT.

The active area ACT may be arranged (or disposed) in the substrate 100. The active area ACT may be provided (or formed) as a part of the substrate 100. The active area ACT may be arranged in the substrate 100 and may extend in a first direction, for example, the x-axis direction. The substrate 100 may be partially recessed, and the active area ACT may be disposed in a recessed portion of the substrate 100. The active area ACT may include a channel region C, and a drain region D and a source region S respectively arranged in the opposite sides of the channel region C. The drain region D and the source region S may each be an area doped with impurities in the substrate 100 including a semiconductor material. The channel region C may overlap the gate electrode GE.

The gate dielectric layer GO may be arranged between the gate electrode GE and the active area ACT. The gate dielectric layer GO may include an inorganic insulating material, for example, a silicon oxide (SiO₂), a silicon nitride (SiNₓ), a SiON, an aluminum oxide (Al₂O₃), a titanium oxide (TiO₂), a tantalum oxide (Ta₂O₅), a hafnium oxide (HfO₂), a zinc oxide (ZnO₂), or the like.

The gate electrode GE may be disposed in the active area ACT. The gate electrode GE may be arranged to intersect the active area ACT and extend in a direction, for example, the y-axis direction. The channel region C of the thin film transistor TFT may be formed in the active area ACT intersecting the gate electrode GE. The gate electrode GE may be disposed on the gate dielectric layer GO. The gate electrode GE may include a conductive material. For example, the gate electrode GE may include a metal nitride, such as a titanium nitride (TiN), a tantalum nitride (TaN), or a tungsten nitride (WN), and/or a metal material, such as aluminum (Al), tungsten (W), copper (Cu), molybdenum (Mo) or the like, or a semiconductor material such as doped polysilicon. The gate electrode GE may be formed in a multilayer or a single layer including the above material.

The interlayer insulating layer 111 may be disposed on the substrate 100, and may cover the thin film transistor TFT. The interlayer insulating layer 111 may include at least one of an oxide, a nitride, and an oxynitride. The interlayer insulating layer 111 may have a single layer structure or a multilayer structure.

A drain electrode DE and a source electrode SE may be positioned on the interlayer insulating layer 111. The drain electrode DE and the source electrode SE may be respectively connected to the drain region D and the source region S of the active area ACT through contact holes provided in the interlayer insulating layer 111. The drain electrode DE and the source electrode SE may include a material having superior conductivity. The drain electrode DE and the source electrode SE may each include a conductive material including Mo, Al, Cu, titanium (Ti), and the like, and may be formed in a multilayer or a single layer including the above material.

The via insulating layer 120 may be disposed on the pixel circuit layer 110. A pixel electrode 210 may be connected (e.g., electrically connected) to the thin film transistor TFT through a contact hole formed in the via insulating layer 120.

The first to third organic light-emitting diodes OLED1, OLED2, and OLED3 may be disposed on the via insulating layer 120. The first to third organic light-emitting diodes OLED1, OLED2, and OLED3 may each have a stack structure of the pixel electrode 210, a light-emitting layer 220, and a counter electrode 230. In an embodiment, the first to third organic light-emitting diodes OLED1, OLED2, and OLED3 may emit white light. In another example, the first to third organic light-emitting diodes OLED1, OLED2, and OLED3 may emit, for example, red light, green light, or blue light (or red light, green light, blue light, or white light). The first to third organic light-emitting diodes OLED1, OLED2, and OLED3 may emit light, and areas where light is emitted may be respectively defined as first to third emission areas EA1, EA2, and EA3.

The pixel electrode 210 may include a lower layer 211, an intermediate layer 212 disposed on the lower layer 211, and an upper layer 213 disposed on the intermediate layer 212. The pixel electrode 210 may be disposed on the via insulating layer 120. The pixel electrode 210 may be disposed on the pixel circuit layer 110, and may be connected (e.g., electrically connected) to the thin film transistor TFT. The pixel electrode 210 may include pixel electrodes that are spaced apart from each other.

The lower layer 211 may be disposed on the via insulating layer 120. The lower layer 211 may be spaced apart from the upper layer 213 with the intermediate layer 212 therebetween. The lower layer 211 may be disposed at the bottom portion of the pixel electrode 210. The lower layer 211 may be a reflective film that reflects light.

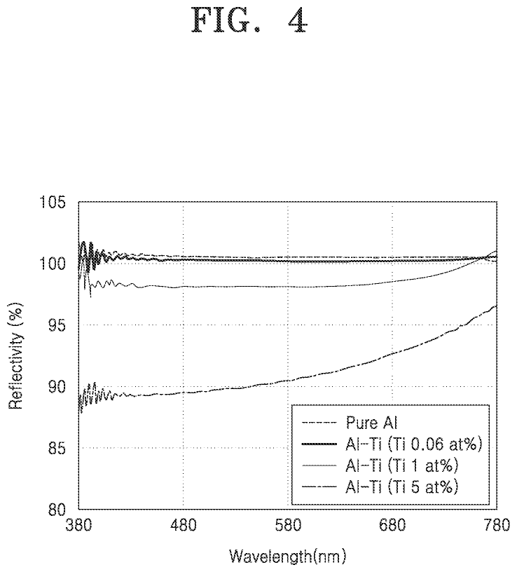

The lower layer 211 may include a conductive material that is readily dry etched. The lower layer 211 may include at least one of aluminum and an aluminum alloy. The lower layer 211 may include, for example, an aluminum-titanium alloy (Al—Ti alloy). In the Al—Ti alloy, the atomic ratio of Ti may be within a range of about 0.01 at % or more and less than about 0.1 at %. An Al—Ti alloy in which the atomic ratio of Ti ranges more than about 0.01 at % may prevent or reduce occurrence of hillock defects in the following heat treatment process. Furthermore, as illustrated in FIG. 4, in case that the Ti atomic ratio of an Al—Ti alloy is less than about 0.1 at %, high reflectivity properties, similar to pure Al, may be obtained. Accordingly, in case that the lower layer 211 is formed of an Al—Ti alloy having a Ti atomic ratio having a range of about 0.01 at % or more and less than about 0.1 at %, the lower layer 211 may have high reflectivity properties and may prevent or reduce the occurrence of hillock defects.

The intermediate layer 212 may be disposed between the lower layer 211 and the upper layer 213. The intermediate layer 212 may be a layer for preventing Galvanic corrosion that occurs in case that the lower layer 211 contacts the upper layer 213. The intermediate layer 212 may include a conductive material that is readily dry etched. The intermediate layer 212 may include, for example, a tungsten oxide (WOₓ) and the like. WOₓ may be readily dry etched, and may prevent corrosion between aluminum or an aluminum alloy and a transparent conductive oxide. Furthermore, as tungsten oxide (WOₓ) has a high work function of about 5.2 eV, in case that the intermediate layer 212 includes WOₓ, the intermediate layer 212 may assist the hole injection properties of the upper layer 213. As the intermediate layer 212 is provided between the lower layer 211 and the upper layer 213, corrosion occurring as the lower layer 211 directly contacts the upper layer 213 may be prevented, and thus, the reliability of the display device 1 may be improved.

The upper layer 213 may be disposed on the intermediate layer 212. The upper layer 213 may be disposed at the top portion of the pixel electrode 210. The upper layer 213 may be a layer into which holes are injected. The upper layer 213 may include a transparent conductive material. The upper layer 213 may include, for example, an indium tin oxide (ITO), an indium zinc oxide (IZO), a zinc oxide (ZnO), an indium oxide (In₂O₃), an indium gallium oxide (IGO), an aluminum zinc oxide (AZO), or the like. In an embodiment, the upper layer 213 may include ITO.

A thickness ta of the upper layer 213 may be within a range of, for example, about 20 Å to about 100 Å. The thickness ta of the upper layer 213 may be particularly within a range of about 20 Å to about 50 Å. In case that the thickness ta of the upper layer 213 is greater than the above range, a defect may occur due to etching residual. In case that the thickness ta of the upper layer 213 is less than the above range, the upper layer 213 may not be readily formed.

The light-emitting layer 220 may be disposed on the pixel electrode 210. The light-emitting layer 220 may be disposed on the via insulating layer 120 to cover the pixel electrode 210. In an embodiment, the light-emitting layer 220 may be integrally formed to cover (e.g., entirely cover) the substrate 100. The light-emitting layer 220 may emit light of a certain color. In an embodiment, the light-emitting layer 220 may include a polymer or a low molecular weight organic material. The light-emitting layer 220 may include an organic light-emitting layer. In another example, it is possible that the light-emitting layer 220 includes an inorganic light-emitting material or quantum dots.

A first functional layer and a second functional layer may be respectively disposed below and above the light-emitting layer 220. The first functional layer may include, for example, a hole transport layer (HTL), or a hole transport layer and a hole injection layer (HIL). The second functional layer may include an electron transport layer (ETL) and/or an electron injection layer (EIL), as elements disposed above the light-emitting layer 220. The first functional layer and/or the second functional layer may be common layers formed to cover (e.g., entirely cover) the substrate 100, like the counter electrode 230 to be described below.

The counter electrode 230 may be disposed on the pixel electrode 210, and may overlap the pixel electrode 210. The counter electrode 230 may be disposed on the light-emitting layer 220. The counter electrode 230 may include a conductive material having a low work function. For example, the counter electrode 230 may include a (semi-)transparent layer including silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), an alloy thereof, or the like. In another example, the counter electrode 230 may further include a layer, such as ITO, IZO, ZnO, or In₂O₃, on the (semi-)transparent layer including the material described above. The counter electrode 230 may be integrally formed to cover (e.g., entirely cover) the substrate 100.

The display device 1 may include the first to third organic light-emitting diodes OLED1, OLED2, and OLED3, and the first to third organic light-emitting diodes OLED1, OLED2, and OLED3 may emit light through the first to third emission areas EA1, EA2, and EA3, thereby providing (or displaying) an image.

The thin film encapsulation layer 300 may be disposed on the counter electrode 230. The thin film encapsulation layer 300 may be arranged to cover the first to third organic light-emitting diodes OLED1, OLED2, and OLED3. The thin film encapsulation layer 300 may include at least one inorganic encapsulation layer and at least one organic encapsulation layer. In an embodiment, the thin film encapsulation layer 300 may include a first inorganic encapsulation layer 310, an organic encapsulation layer 320 on the first inorganic encapsulation layer 310, and a second inorganic encapsulation layer 330 on the organic encapsulation layer 320.

The first inorganic encapsulation layer 310 and the second inorganic encapsulation layer 330 each may include one or more inorganic materials among Al₂O₃, TiO₂, Ta₂O₅, HfO₂, ZnO₂, SiO₂, SiNₓ, and SiON. The organic encapsulation layer 320 may include a polymer-based material. The polymer-based material may include acrylic resin, epoxy-based resin, polyimide, polyethylene, and the like. In an embodiment, the organic encapsulation layer 320 may include acrylate. The organic encapsulation layer 320 may be formed by curing a monomer or coating a polymer. The organic encapsulation layer 320 may be transparent.

The color filter layer 400 may be disposed on the thin film encapsulation layer 300. The color filter layer 400 may include a first color filter 400A, a second color filter 400B, and a third color filter 400C. The first to third color filters 400A, 400B, and 400C may be arranged to correspond to the pixel electrodes 210a of the first to third organic light-emitting diodes OLED1, OLED2, and OLED3, respectively. For example, the first color filter 400A may be arranged to overlap the pixel electrode 210 of the first organic light-emitting diode OLED1 in the direction perpendicular to the substrate 100, for example, the z-axis direction. For example, the second color filter 400B may be arranged to overlap the pixel electrode 210 of the second organic light-emitting diode OLED2 in the direction perpendicular to the substrate 100, for example, the z-axis direction. For example, the third color filter 400C may be arranged to overlap the pixel electrode 210 of the third organic light-emitting diode OLED3 in the direction perpendicular to the substrate 100, for example, the z-axis direction.

The first to third color filters 400A, 400B, and 400C may include photosensitive resin. The first to third color filters 400A, 400B, and 400C may each include pigment or dye indicating an intrinsic color.

The first to third color filters 400A, 400B, and 400C may each transmit red light, green light, or blue light. For example, the first color filter 400A may be a red color filter that selectively transmits red light among ling emitted from the light-emitting layer 220. For example, the first color filter 400A may transmit only light having a wavelength of about 630 nm to about 780 nm. For example, the second color filter 400B may be a green color filter that selectively transmits green light among ling emitted from the light-emitting layer 220. For example, the second color filter 400B may transmit only light having a wavelength of about 495 nm to about 570 nm. For example, the third color filter 400C may be a blue color filter that selectively transmits blue light among ling emitted from the light-emitting layer 220. For example, the third color filter 400C may transmit only light having a wavelength of about 450 nm to about 495 nm.

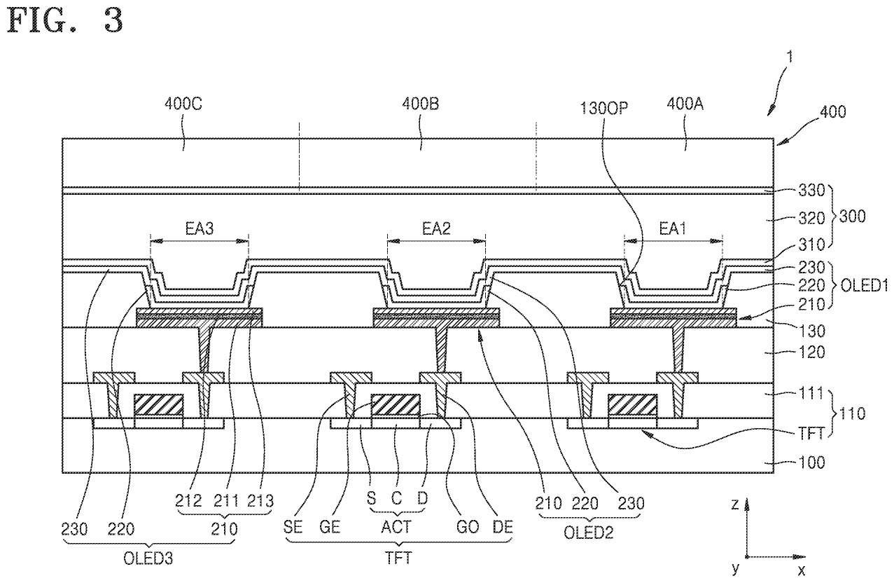

FIG. 3 is a schematic cross-sectional view of the display device 1 according to an embodiment. In FIG. 3, as the same reference numerals as those in FIG. 2 denote the same elements, redundant descriptions are omitted, and only changed parts are described.

Referring to FIG. 3, the first to third organic light-emitting diodes OLED1, OLED2, and OLED3 may emit, for example, red light, green light (or blue light, or red light, green light, blue light, or white light).

In an embodiment, the pixel electrode 210 and a pixel defining layer 130 may be disposed on the via insulating layer 120. The pixel defining layer 130 may include an opening 1300P that exposes at least a portion of the pixel electrode 210. For example, at least a portion of a surface of the pixel electrode 210 may be exposed by the opening 1300P defined in the pixel defining layer 130. In an embodiment, the first to third emission areas EA1, EA2, and EA3 may be defined as areas exposed by the opening 1300P of the pixel defining layer 130. The pixel defining layer 130 may include an organic insulating material and/or an inorganic insulating material. In another example, the pixel defining layer 130 may be omitted.

In an embodiment, the light-emitting layer 220 may be arranged to correspond to the pixel electrode 210. The light-emitting layer 220 of each of the first to third organic light-emitting diodes OLED1, OLED2, and OLED3 corresponding to the pixel electrode 210 of each of the first to third organic light-emitting diodes OLED1, OLED2, and OLED3 may emit different light. For example, the light-emitting layer 220 of the first organic light-emitting diode OLED1 may emit red light, the light-emitting layer 220 of the second organic light-emitting diode OLED2 may emit green light, and the light-emitting layer 220 of the third organic light-emitting diode OLED3 may emit blue light.

The color filter layer 400 may be disposed on the thin film encapsulation layer 300. The color filter layer 400 may include the first color filter 400A, the second color filter 400B, and the third color filter 400C. The first to third color filters 400A, 400B, and 400C may be arranged to respectively correspond to the first to third organic light-emitting diodes OLED1, OLED2, and OLED3, to improve the color gamut of light emitted by each of the first to third organic light-emitting diodes OLED1, OLED2, and OLED3. For example, to improve the color gamut of red light, the first color filter 400A may be arranged to overlap the pixel electrode 210 of the first organic light-emitting diode OLED1 in the direction perpendicular to the substrate 100, for example, the z-axis direction. For example, to improve the color gamut of green light, the second color filter 400B may be arranged to overlap the pixel electrode 210 of the second organic light-emitting diode OLED2 in the direction perpendicular to the substrate 100, for example, the z-axis direction. For example, to improve the color gamut of blue light, the third color filter 400C may be arranged to overlap the pixel electrode 210 of the third organic light-emitting diode OLED3 in the direction perpendicular to the substrate 100, for example, the z-axis direction.

FIG. 4 is a graph showing the reflectivities of aluminum and an aluminum alloy.

Referring to FIG. 4, the reflectivities of Al and an Al—Ti alloy according to the atomic ratio of Ti are shown. Pure Al may have a high reflectivity of about 100%. An Al—Ti alloy having a Ti atomic ratio of about 0.06 at % may have a high reflectivity of about 100%, similar to pure Al. An Al—Ti alloy having a Ti atomic ratio of about 1 at % may have reflectivity of about 98%. An Al—Ti alloy having a Ti atomic ratio of about 5 at % may have a remarkably low reflectivity, compared with a case of the Ti atomic ratio of about 0.06 at %. Accordingly, as the reflectivity of an Al—Ti alloy having a Ti atomic ratio of less than about 0.1 at % has high reflectivity properties, similar to pure Al, the above Al—Ti alloy may be used instead of pure Al as a reflective film of a pixel electrode.

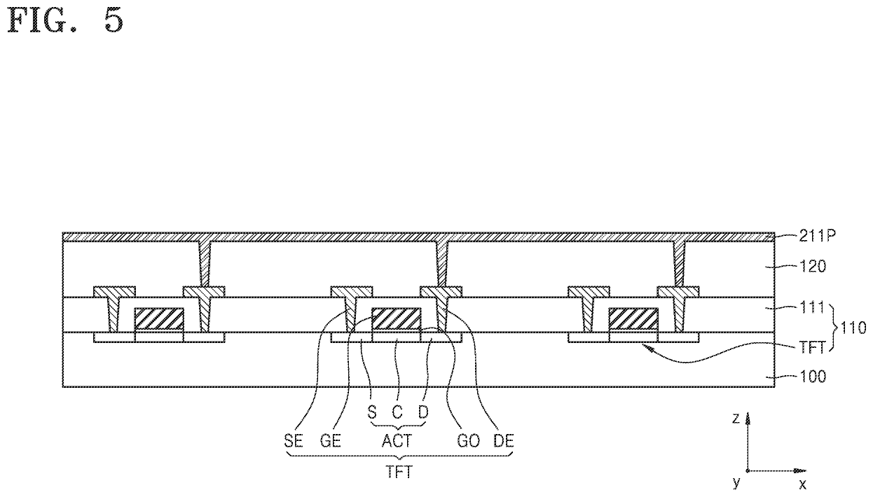

FIGS. 5 to 9 are schematic cross-sectional views of a method of manufacturing the display device 1, according to an embodiment. FIGS. 5 to 9 show a method of manufacturing the display device 1, according to the cross-sections corresponding to FIG. 2.

Referring to FIG. 5, the substrate 100, the pixel circuit layer 110 including the thin film transistor TFT, the via insulating layer 120 disposed on the pixel circuit layer 110, and a preliminary lower conductive layer 211P disposed on the via insulating layer 120 and connected (e.g., electrically connected) to the thin film transistor TFT may be formed.

The substrate 100 may include a Group IV semiconductor, a Group III-V compound semiconductor, or a Group II-VI compound semiconductor. The substrate 100 may include, for example, a silicon layer.

The gate dielectric layer GO and the gate electrode GE may be sequentially formed on the substrate 100. The gate dielectric layer GO and the gate electrode GE may be formed by an atomic layer deposition (ALD) method or a chemical vapor deposition (CVD) method.

The gate dielectric layer GO may include an inorganic insulating material, for example, SiO₂, SiNₓ, SiON, Al₂O₃, TiO₂, Ta₂O₅, HfO₂, ZnO₂, or the like. The gate electrode GE may include, for example, a metal nitride, such as TiN, TaN, or WN and/or a metal material, such as Al, W, Cu, Mo, or the like, or a semiconductor material such as doped polysilicon.

For example, the drain region D and the source region S may be formed by performing an ion-injection process. For example, the interlayer insulating layer 111 may be formed on the substrate 100 to cover the gate dielectric layer GO and the gate electrode GE. After forming contact holes respectively connected to the drain region D and the source region S by removing a portion of the interlayer insulating layer 111, the drain electrode DE and the source electrode SE may be formed. For example, the via insulating layer 120 may be formed on the interlayer insulating layer 111.

For example, the preliminary lower conductive layer 211P may be formed on the via insulating layer 120. The preliminary lower conductive layer 211P may include a conductive material that is readily dry etched. The preliminary lower conductive layer 211P may include at least one of aluminum and an aluminum alloy. The preliminary lower conductive layer 211P may include, for example, an Al—Ti alloy. In case that the preliminary lower conductive layer 211P includes an Al—Ti alloy, the atomic ratio of Ti in the Al—Ti alloy may be within a range of about 0.01 at % or more and less than about 0.1 at %.

The preliminary lower conductive layer 211P may be formed by a deposition method, for example, a chemical vapor deposition method, a plasma enhanced CVD (PECVD) method, a low pressure CVD (LPCVD) method, a physical vapor deposition (PVD) method, a sputtering method, an atomic layer deposition (ALD) method, and the like.

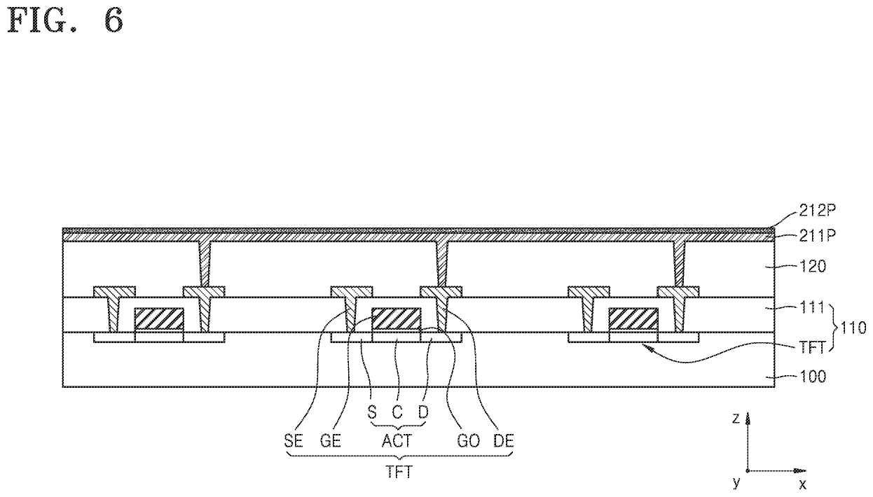

Referring to FIG. 6, a preliminary intermediate conductive layer 212P may be formed on the preliminary lower conductive layer 211P. The preliminary intermediate conductive layer 212P may be a layer for preventing Galvanic corrosion between the preliminary lower conductive layer 211P and a preliminary upper conductive layer 213P. The preliminary intermediate conductive layer 212P may include a conductive material that is readily dry etched. The preliminary intermediate conductive layer 212P may include, for example, tungsten oxide (WOₓ) and the like. WOₓ may be readily dry etched, and may prevent corrosion between aluminum or an aluminum alloy and a transparent conductive oxide.

The preliminary intermediate conductive layer 212P may be formed by a deposition method, for example, a CVD method, a PECVD method, an LPCVD method, a PVD method, a sputtering method, an ALD method, and the like.

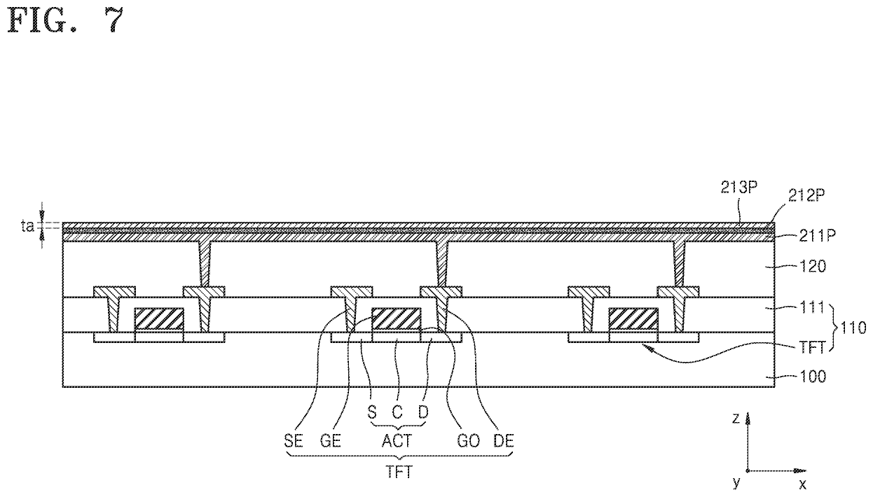

Referring to FIG. 7, the preliminary upper conductive layer 213P may be formed on the preliminary intermediate conductive layer 212P. The preliminary upper conductive layer 213P may include a transparent conductive material. For example, the preliminary upper conductive layer 213P may include ITO, IZO, ZnO, In₂O₃, IGO, AZO, or the like. In an embodiment, the preliminary upper conductive layer 213P may include ITO.

The thickness ta of the preliminary upper conductive layer 213P may be within a range of, for example, about 20 Å to about 100 Å. The thickness ta of the preliminary upper conductive layer 213P may be particularly within a range of about 20 Å to about 50 Å.

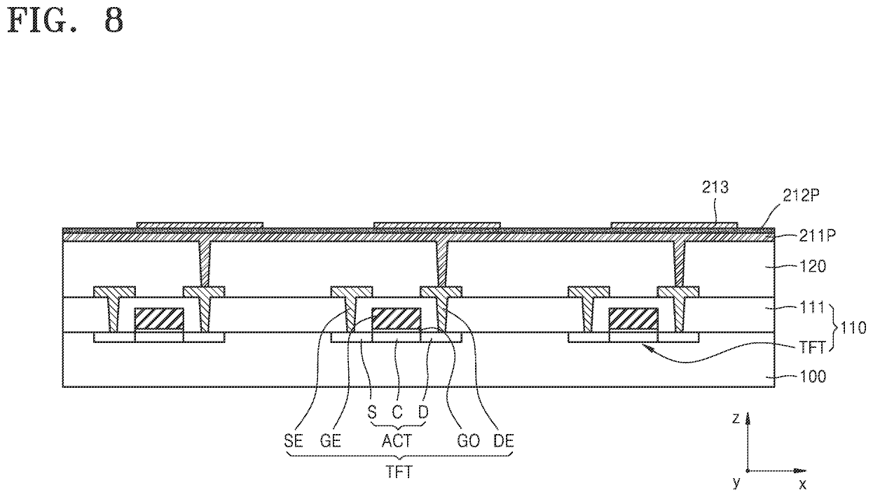

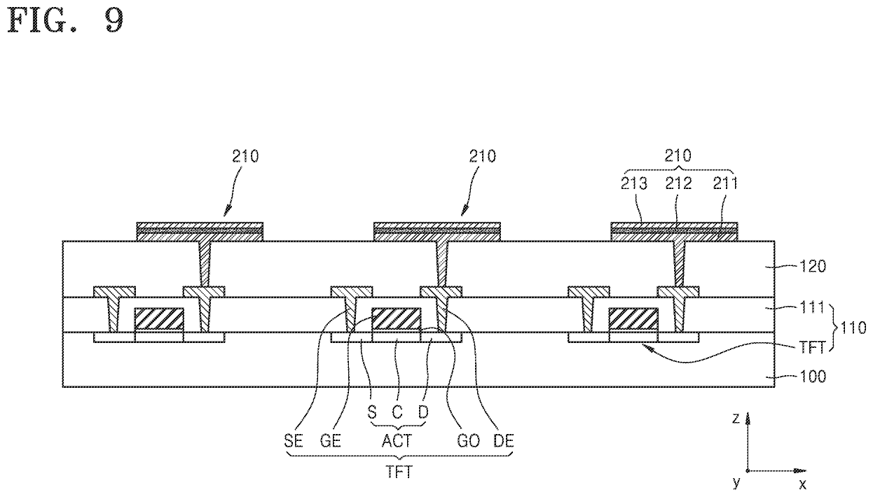

Referring to FIGS. 8 and 9, after etching the preliminary upper conductive layer 213P, the pixel electrode 210 may be formed by etching the preliminary intermediate conductive layer 212P and the preliminary lower conductive layer 211P.

FIG. 8 illustrates a first etching operation of forming the upper layer 213 by etching the preliminary upper conductive layer 213P. The upper layer 213 may be formed by etching a portion of the preliminary upper conductive layer 213P. The preliminary upper conductive layer 213P may be partially removed by dry etching. As described with reference to FIG. 7, as the thickness ta of the preliminary upper conductive layer 213P is a thin thickness in a range of, for example, about 20 Å to about 100 Å, the preliminary upper conductive layer 213P may be removed by physical or chemical dry etching. For example, the preliminary upper conductive layer 213P may be removed by a sputtering etching process or an etching process, which is performed by plasma.

FIG. 9 illustrates a second etching operation of forming the intermediate layer 212 and the lower layer 211 by etching the preliminary intermediate conductive layer 212P and the preliminary lower conductive layer 211P. For example, the intermediate layer 212 may be formed by removing a portion of the preliminary intermediate conductive layer 212P. For example, the lower layer 211 may be formed by removing a portion of the preliminary lower conductive layer 211P. The preliminary intermediate conductive layer 212P and the preliminary lower conductive layer 211P may each be partially removed by dry etching. The etching process of the preliminary intermediate conductive layer 212P and the preliminary lower conductive layer 211P may be performed by using a chlorine-based etching gas.

Referring back to FIG. 2, the light-emitting layer 220 may be formed on the via insulating layer 120 to cover the pixel electrode 210, and the first to third organic light-emitting diodes OLED1, OLED2, and OLED3 may be formed by forming the counter electrode 230 on the light-emitting layer 220. In an embodiment, the light-emitting layer 220 may include an organic material including a fluorescent or phosphorescent material for emitting white light. In another example, the light-emitting layer 220 may include an organic material including a fluorescent or phosphorescent material for emitting red light, green light, blue light, or white light. The light-emitting layer 220 may include a low molecular weight organic material or a polymer organic material, and a functional layer such as HTL, HIL, ETL, EIL, and the like may be selectively further disposed below and above the organic light-emitting layer. The light-emitting layer 220 may be formed as an integral layer across the pixel electrodes 210, but embodiments are not limited thereto. For example, the light-emitting layer 220, as illustrated in FIG. 3, may be arranged corresponding to each of the pixel electrodes 210.

The counter electrode 230 may be formed by various deposition methods, such as a CVD method, a PECVD method, an LPCVD method, a PVD method, a sputtering method, an ALD method, and the like.

For example, the thin film encapsulation layer 300 including the first inorganic encapsulation layer 310, the organic encapsulation layer 320 on the first inorganic encapsulation layer 310, and the second inorganic encapsulation layer 330 may be formed on the first to third organic light-emitting diodes OLED1, OLED2, and OLED3. For example, a color filter layer 400 may be formed on the thin film encapsulation layer 300.

As the pixel electrode according to one or more embodiments includes a lower layer including aluminum or an aluminum alloy, an upper layer including a transparent conductive oxide, and an intermediate layer disposed between the lower layer and the upper layer and including a tungsten oxide, the reliability of a display device may be improved. However, the scope of the disclosure is not limited by the above effects.

In concluding the detailed description, those skilled in the art will appreciate that many variations and modifications may be made to the embodiments without substantially departing from the principles and spirit and scope of the disclosure. Therefore, the disclosed embodiments are used in a generic and descriptive sense only and not for purposes of limitation.

What is claimed is:

1. A display device comprising:
a substrate;
a pixel circuit layer disposed on the substrate and including at least one thin film transistor; and
a pixel electrode disposed on the pixel circuit layer and electrically connected to the at least one thin film transistor,
wherein the pixel electrode comprises:
a lower layer including aluminum,
an intermediate layer disposed on the lower layer and including a tungsten oxide, and
an upper layer disposed on the intermediate layer and including a transparent conductive oxide.

2. The display device of claim 1, wherein the lower layer includes an Al—Ti alloy.

3. The display device of claim 2, wherein, in the Al—Ti alloy, an atomic ratio of titanium (Ti) has a range of about 0.01 at % to about 0.1 at %.

4. The display device of claim 1, wherein the upper layer includes an indium tin oxide (ITO).

5. The display device of claim 1, wherein a thickness of the upper layer is in a range of about 20 Å to about 100 Å.

6. The display device of claim 1, wherein the substrate is a semiconductor substrate including a semiconductor material.

7. The display device of claim 1, further comprising:
a light-emitting layer disposed on the pixel electrode;
a counter electrode disposed on the light-emitting layer; and
a thin film encapsulation layer disposed on the counter electrode.

8. The display device of claim 7, further comprising a red color filter, a green color filter, and a blue color filter disposed on the thin film encapsulation layer.

9. A display device comprising:
a substrate;
a pixel circuit layer disposed on the substrate and including at least one thin film transistor; and
a pixel electrode disposed on the pixel circuit layer and electrically connected to the at least one thin film transistor,
wherein the pixel electrode comprises:
a lower layer including aluminum,
an intermediate layer disposed on the lower layer and including a tungsten oxide, and
an upper layer disposed on the intermediate layer and including an indium tin oxide (ITO).

10. The display device of claim 9, wherein
the lower layer includes an Al—Ti alloy, and
in the Al—Ti alloy, an atomic ratio of titanium (Ti) has a range of about 0.01 at % to about 0.1 at %.

11. The display device of claim 9, wherein a thickness of the upper layer is in a range of about 20 Å to about 100 Å.

12. The display device of claim 9, wherein the substrate includes a semiconductor substrate.

13. A method of manufacturing a display device, the method comprising:
forming, on a substrate, a pixel circuit layer including at least one thin film transistor;
forming, on the pixel circuit layer, a preliminary lower conductive layer electrically connected to the at least one thin film transistor and including aluminum;
forming, on the preliminary lower conductive layer, a preliminary intermediate conductive layer including a tungsten oxide;
forming, on the preliminary intermediate conductive layer, a preliminary upper conductive layer including a transparent conductive oxide; and
forming a pixel electrode including a lower layer, an intermediate layer, and an upper layer by dry etching the preliminary lower conductive layer, the preliminary intermediate conductive layer, and the preliminary upper conductive layer.

14. The method of claim 13, wherein the forming of the pixel electrode comprises:
a first etching operation of dry etching the preliminary upper conductive layer; and
a second etching operation of dry etching the preliminary lower conductive layer and the preliminary intermediate conductive layer.

15. The method of claim 14, wherein the second etching operation of dry etching the preliminary lower conductive layer and the preliminary intermediate conductive layer is performed by using a chlorine-based etching gas.

16. The method of claim 13, wherein the preliminary lower conductive layer includes an Al—Ti alloy.

17. The method of claim 16, wherein, in the Al—Ti alloy, an atomic ratio of titanium (Ti) has a range of about 0.01 at % to about 0.1 at %.

18. The method of claim 13, wherein the preliminary upper conductive layer includes an indium tin oxide (ITO).

19. The method of claim 13, wherein a thickness of the preliminary upper conductive layer is in a range of about 20 Å to about 100 Å.

20. The method of claim 13, wherein the substrate includes a semiconductor substrate.
